(19) United States
(12) Patent Application Publication
(10) Pub. No.: US 2026/0239775 A1
(43) Pub. Date: Aug. 13, 2026

(54) LED LIGHT SOURCE MODULE, DISPLAY APPARATUS AND MANUFACTURING METHOD OF THE SAME

(71) Applicant: Samsung Electronics Co., Ltd., Suwon-si (KR)

(72) Inventor: Hanhyoung KIM, Suwon-si (KR)

(73) Assignee: Samsung Electronics Co., Ltd., Suwon-si (KR)

(21) Appl. No.: 19/316,544

(22) Filed: Sep. 2, 2025

(30) Foreign Application Priority Data
Feb. 11, 2025 (KR) 10-2025-0017509

(51) Int. Cl. H10H 20/01; H10H 29/01

(52) U.S. Cl. CPC H10H 20/034; H10H 20/01335; H10H 20/017; H10H 20/019; H10H 29/011

(57) ABSTRACT

A manufacturing method of a light emitting diode (LED) module includes forming a semiconductor stack body by sequentially growing a first conductive semiconductor layer, an active layer, and a second conductive semiconductor layer on a growth substrate; forming a mask pattern on the semiconductor stack body; forming an LED cell by etching one or more portions of the second conductive semiconductor layer, the active layer, and the first conductive semiconductor layer; and forming a gap-fill insulating layer on the LED cell, in which the forming the LED cell further includes: a first operation of partially removing the semiconductor stack body, a second operation of forming an etching protective layer by covering an etched surface of the semiconductor stack body or forming a bond on the etched surface of the semiconductor stack body, and a third operation of exposing the semiconductor stack body by partially removing the etching protective layer.

### CROSS-REFERENCE TO RELATED APPLICATION(S)

This application claims benefit of priority to Korean Patent Application No. 10-2025-0017509 filed on Feb. 11, 2025, in the Korean Intellectual Property Office, the disclosure of which is incorporated herein by reference in its entirety.

### BACKGROUND

The present disclosure relates to an LED light source module, a display apparatus and a manufacturing method of the same.

Semiconductor light emitting diodes (LEDs) are used not only as light sources for lighting devices but also as light sources for various electronic products. In one or more examples, LEDs are widely used as light sources for various display apparatuses such as TVs, mobile phones, PCs, notebook PCs, PDAs, and the like.

Existing display apparatuses are mainly comprised of display panels formed of liquid crystal displays (LCDs) and backlights, but recently, display apparatuses have also been developed in a form that does not require a separate backlight by using the LED as a pixel. Such display apparatuses may be miniaturized and may implement high-brightness display apparatuses having superior light efficiency as compared to an LCD. However, these types of display apparatuses with miniaturized components (e.g., micro LEDs) experience sidewall damage.

### SUMMARY

An aspect of the present disclosure is to provide an LED light source module having excellent luminous efficiency and a manufacturing method thereof.

An aspect of the present disclosure is to provide a display apparatus having excellent luminous efficiency and a manufacturing method thereof.

According to an aspect of the disclosure, a manufacturing method of a light emitting diode (LED) module includes forming a semiconductor stack body by sequentially growing a first conductive semiconductor layer, an active layer, and a second conductive semiconductor layer on a growth substrate; forming a mask pattern on the semiconductor stack body; forming an LED cell by etching one or more portions of the second conductive semiconductor layer, the active layer, and the first conductive semiconductor layer; and forming a gap-fill insulating layer on the LED cell, in which the forming the LED cell further includes: a first operation of partially removing the semiconductor stack body, a second operation of forming an etching protective layer by covering an etched surface of the semiconductor stack body or forming a bond on the etched surface of the semiconductor stack body, and a third operation of exposing the semiconductor stack body by partially removing the etching protective layer, in which at least a portion of a surface of the LED cell comprises a cell wave pattern including a cell concave portion recessed inwardly of the LED cell and a cell convex portion protruding outwardly of the LED cell.

According to an aspect of the disclosure, a manufacturing method of a light emitting diode (LED) module, includes: forming a semiconductor stack body by sequentially growing a first conductive semiconductor layer, an active layer and a second conductive semiconductor layer on a growth substrate; and forming an LED cell by etching one or more portions of the second conductive semiconductor layer, the active layer, and the first conductive semiconductor layer, in which the forming the LED cell comprises a cycle in which at least one of an operation of etching the semiconductor stack body and an operation of forming an etching protective layer on the semiconductor stack body are repeatedly performed, and in which the etching protective layer has a protective wave pattern comprising at least one protective concave portion recessed inwardly of the LED cell and at least one protective convex portion protruding outwardly from the LED cell in a portion covering a surface of the LED cell.

According to an aspect of the disclosure, a manufacturing method of an LED module, including forming a semiconductor stack body comprising gallium nitride on a growth substrate; forming a contact electrode on the semiconductor stack body; forming a mask pattern on the contact electrode; and forming an LED cell by repeatedly performing a first etching process, in which the first etching process includes: partially removing the semiconductor stack body; forming an etching protective layer by depositing a protective material on an etched surface of the semiconductor stack body, and exposing the semiconductor stack body by partially removing the etching protective layer, in which the partially removing the semiconductor stack body in the first etching process forms a recessed cell concave portion on a surface of the LED cell, and in which the recessed cell concave portion comprises a portion overlapping the contact electrode.

A display apparatus according to example embodiments may include: a circuit board including a driving circuit; a pixel array disposed on the circuit board and having pixel units respectively including a plurality of sub-pixels arranged therein; and a plurality of microlenses disposed on each of the plurality of sub-pixels, and the pixel array may include a plurality of LED cells, provided as light sources for the plurality of sub-pixels and each of which includes a first conductive semiconductor layer, an active layer and a second conductive semiconductor layer sequentially stacked, and a side surface of each of the plurality of LED cells may include a cell wave pattern in which a plurality of cell concave portions recessed inwardly of the side surface and a plurality of cell convex portions protruding outwardly of the side surface are repetitively disposed.

At least a portion of a process of forming micro LED cells may be performed by a process of repeating etching and deposition, thereby preventing side damage of micro LED cells and increasing light efficiency.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of a display apparatus according to example embodiments;

FIG. 2 is an enlarged partial plan view of a portion of the display apparatus of FIG. 1;

FIG. 3 is a schematic cross-sectional view of a display apparatus according to example embodiments;

FIGS. 4A, 4B, 4C, 4D, 4E, 4F, 4G and 4H are partial cross-sectional views illustrating an enlarged portion of the display apparatus of FIG. 3;

FIG. 5 is a driving circuit diagram implemented in a display apparatus according to example embodiments;

FIGS. 6, 11A, 11B, 11C, 11D, 11E, 11F and 11G are cross-sectional views of major processes illustrating a manufacturing method of a display apparatus according to example embodiments;

FIGS. 7A, 7B, 7C, 7D, and 7E are partial cross-sectional views of major processes illustrating a manufacturing method of a display apparatus according to example embodiments;

FIG. 8 is a partial cross-sectional view of major processes illustrating a manufacturing method of a display apparatus according to example embodiments;

FIG. 9 is a partial cross-sectional view of major processes illustrating a manufacturing method of a display apparatus according to example embodiments;

FIGS. 10A and 10B are partial cross-sectional views of major processes illustrating a manufacturing method of a display apparatus according to example embodiments; and

FIG. 12 is a schematic diagram of an electronic device including a display apparatus according to example embodiments.

### DETAILED DESCRIPTION

Hereinafter, it may be understood that expressions such as “on,” “above,” “upper,” “below”,” “beneath,” “lower,” and “side” merely indicated based on drawings unless otherwise stated.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

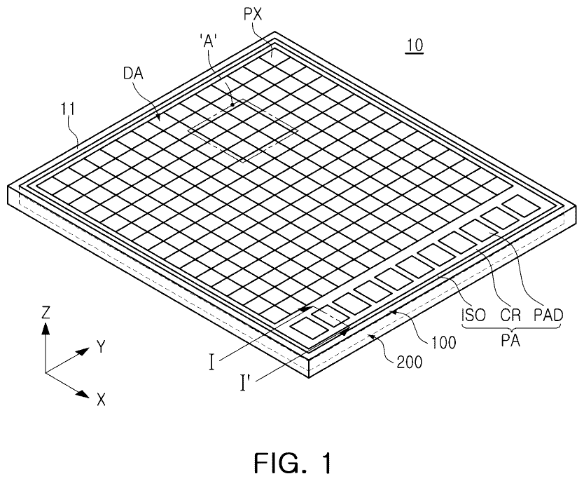

FIG. 1 is a schematic perspective view of a display apparatus according to example embodiments.

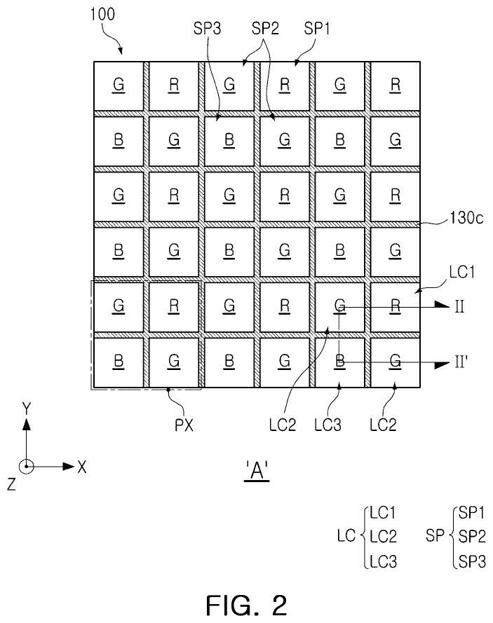

FIG. 2 is an enlarged partial plan view of a portion of the display apparatus of FIG. 1. FIG. 2 is an enlarged view of region ‘A’ of FIG. 1

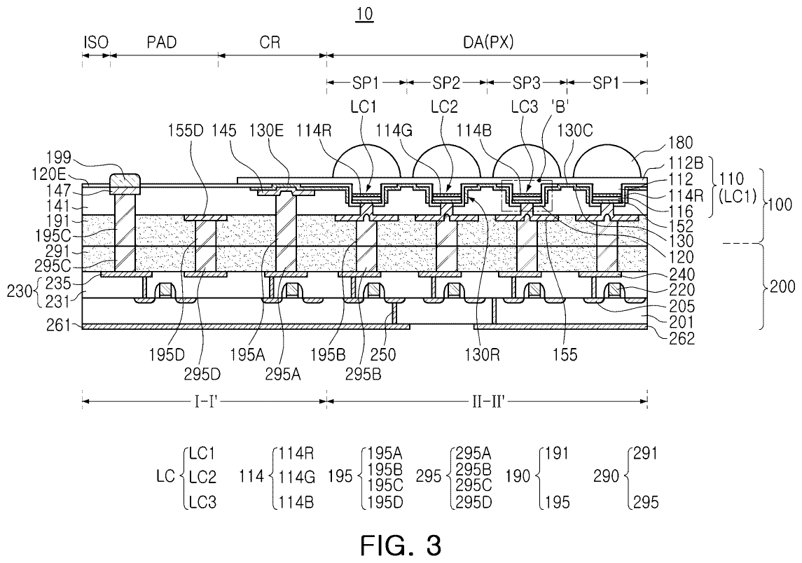

FIG. 3 is a schematic cross-sectional view of a display apparatus according to example embodiments. FIG. 3 illustrates a cross-section taken along cutting line I-I′ of the display apparatus of FIG. 1 and a cross-section taken along cutting line II-II of the display apparatus of FIG. 2.

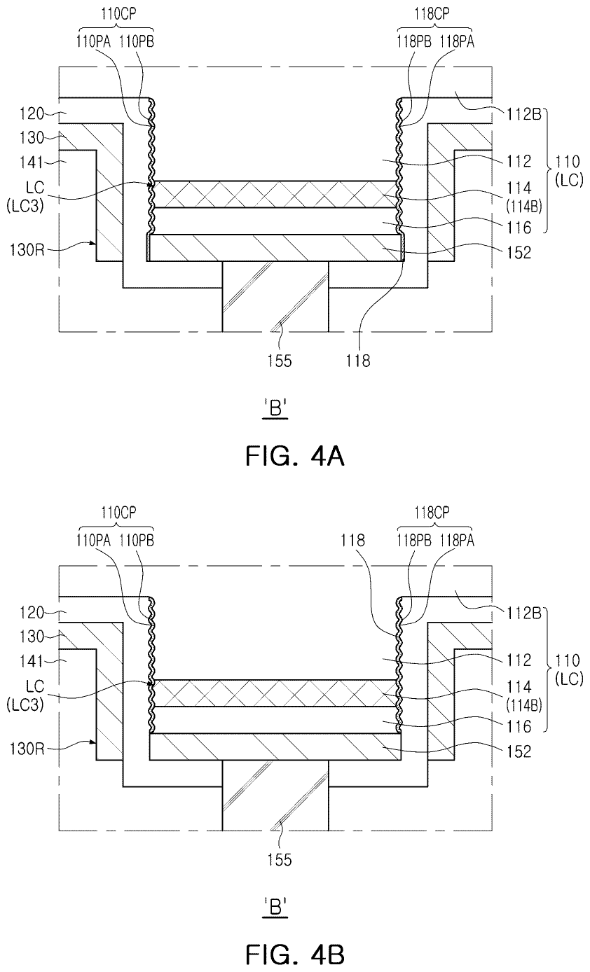

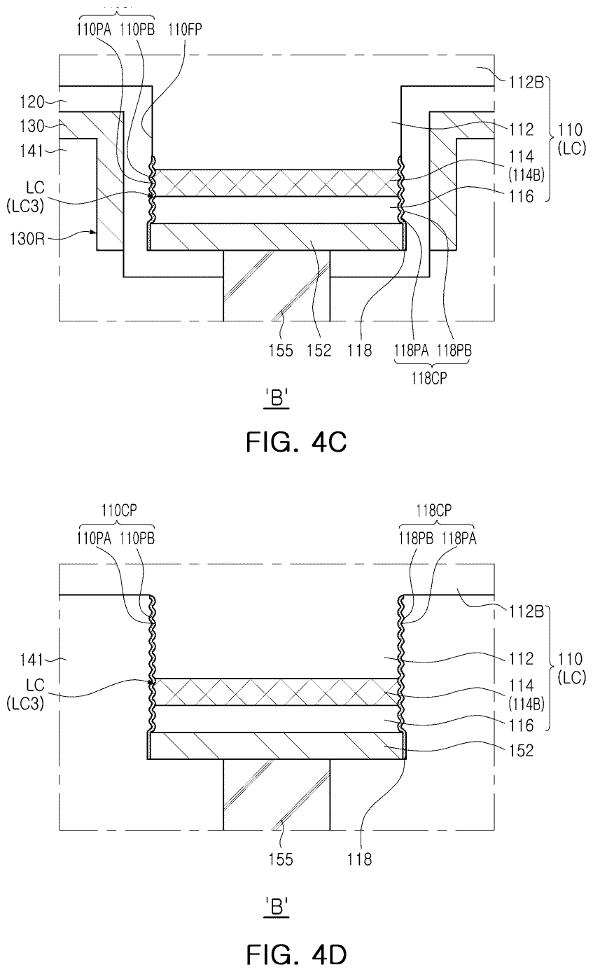

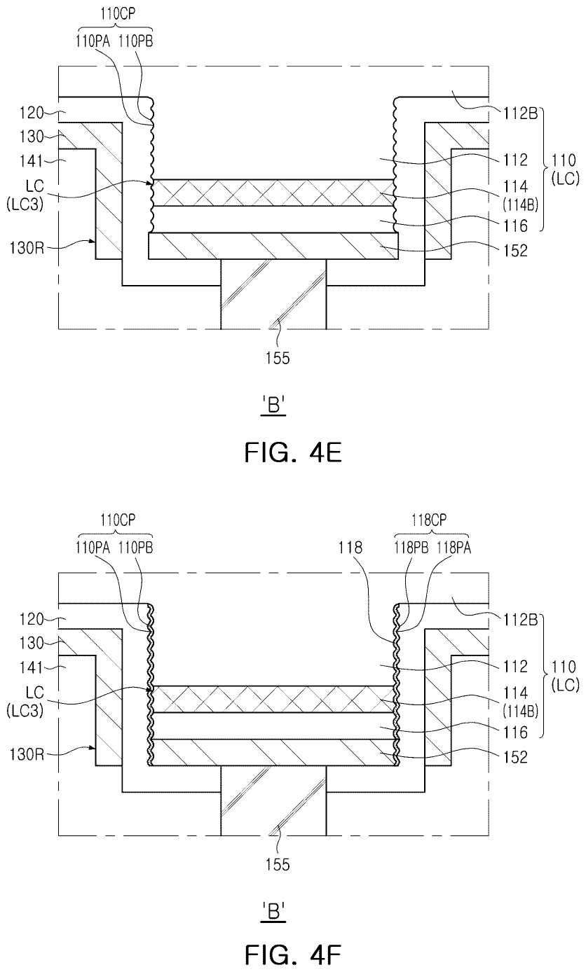

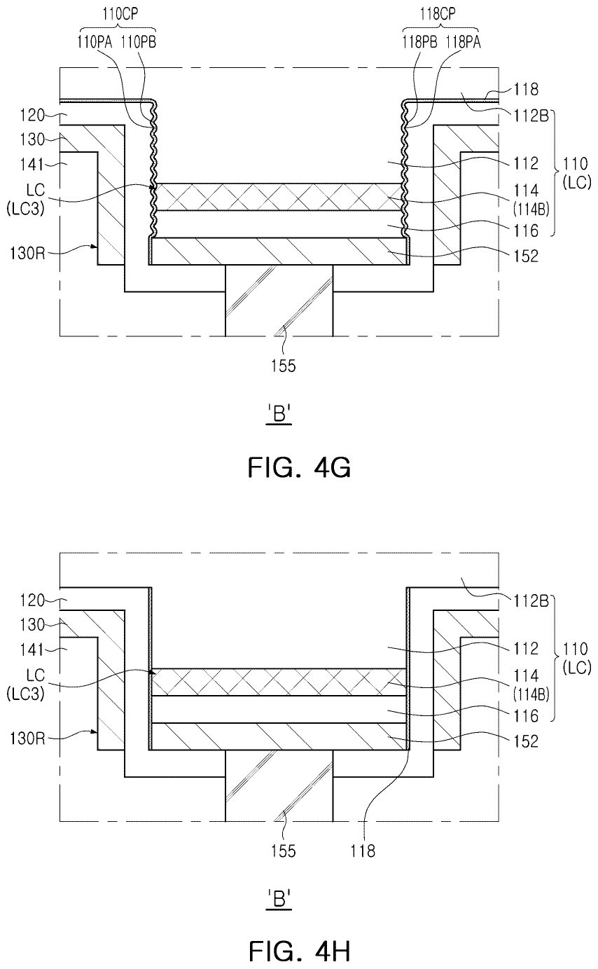

FIGS. 4A, 4B, 4C, 4D, 4E, 4F, 4G and 4H are partial cross-sectional views illustrating an enlarged portion of the display apparatus of FIG. 3. FIG. 4A is an enlarged view illustrating region ‘B’ of FIG. 3. FIGS. 4B to 4H illustrate other example embodiments of FIG. 4A.

Referring to FIGS. 1 to 3 and 4A, a display apparatus 10 according to one or more example embodiments includes a circuit board 200 including driving circuits, and a pixel array 100 disposed on the circuit board 200 and having a plurality of pixels PX arranged therein. In one or more examples, the display apparatus 10 may further include a frame 11 (e.g., bezel) surrounding the circuit board 200 and the pixel array 100.

The circuit board 200 may include a driving circuit including thin film transistor (TFT) cells. In some example embodiments, the circuit board 200 may additionally include other circuits in addition to the driving circuits for the display apparatus. In some example embodiments, the circuit board 200 may include a flexible board, and the display apparatus 10 may be implemented as a display apparatus having a curved profile.

The pixel array 100 may include a display area DA and a peripheral area PA disposed at least on one side of the display area DA. The display area DA may include an LED module for display. The pixel array 100 may include a display area DA in which a plurality of pixels PX are arranged. The peripheral area PA may include pad areas PAD, a connection area CR connecting the plurality of pixels PX and the pad areas PAD, and an edge area ISO.

Each of the plurality of pixels PX may include first to third sub-pixels SP1, SP2 and SP3 configured to emit light of different colors in order to provide a color image. For example, the first to third sub-pixels SP1, SP2 and SP3 may be configured to emit red (R) light, green (G) light, and blue (B) light, respectively. However, as understood by one of ordinary skill in the art, the embodiments are not limited to this configuration where a pixel may include fewer or more sub-pixels. For example, a pixel may include four sub-pixels SP1, SP2, SP3, and SP4 configured to emit cyan (C) light, magenta (M) light, yellow (Y), and key/black (K) light, respectively.

In some example embodiments, in each pixel PX (also referred to as “a pixel unit” or “pixel circuit”), the first to third sub-pixels SP1, SP2 and SP3 may be arranged in a Bayer pattern. As illustrated in FIG. 2, each pixel PX may include first and third sub-pixels SP1 and SP3 (e.g., red (R) and blue (B)) arranged in a first diagonal direction and two second sub-pixels (SP2) (e.g., green (G)) arranged in a second diagonal direction, intersecting the first diagonal direction. In one or more example embodiments, each pixel PX is illustrated as having the first to third sub-pixels SP1, SP2 and SP3 arranged in a 2×2 Bayer pattern. The present disclosure is not limited thereto, and in other example embodiments, each pixel PX may be configured in a different arrangement, such as 3×3 or 4×4. In one or more examples, in some example embodiments, each pixel PX may include a sub-pixel configured to emit a color other than the illustrated colors (R, G and B), for example, yellow light. In the pixel array 100 of FIG. 1, the plurality of pixels PX are illustrated as having a 15×15 arrangement form, but the number of rows and columns may be implemented as any suitable number, for example, 1,024×768 or 1,800×1,350. For example, depending on the desired resolution, the plurality of pixels PX may have a different arrangement.

The frame 11 may be a guide structure surrounding the pixel array 100. The frame 11 may include at least one of materials such as polymer, ceramic, semiconductor, or metal. For example, the frame 11 may include a black matrix. However, the frame 11 is not limited to a black matrix, and may include a white matrix or a structure of another color depending on the purpose of the display apparatus 10. For example, the white matrix may include a reflective material or a scattering material. The display apparatus 10 of FIG. 1 is exemplified as having a rectangular planar structure, but may have a different shape according to example embodiments.

The plurality of LED cells LC1, LC2 and LC3 may be formed to have micro LED structures, respectively, to correspond to the first to third sub-pixels SP1, SP2 and SP3. The LED cells LC may be arranged in a plurality of columns and a plurality of rows in a planar view (see FIG. 2). The plurality of LED cells LC1, LC2 and LC3 may be provided as light sources for the sub-pixels SP1, SP2 and SP3 and may include active layers 114R, 114G and 114B emitting light of different wavelengths. Each of the first LED cells LC1 may include a first active layer 114R configured to emit red light, for example, light having a wavelength of 620 nm to 660 nm, and may be provided as a red sub-pixel SP1. Each of the second LED cells LC2 may include a second active layer 114G configured to emit green light, for example, light having a wavelength of 510 nm to 550 nm, and may be provided as a green sub-pixel SP2. Each of the third LED cells LC3 may include a third active layer 114B configured to emit blue light, for example, light having a wavelength of 430 nm to 480 nm, and may be provided as a blue sub-pixel SP3.

FIG. 3 is a partially enlarged cross-sectional view of a display apparatus according to one or more example embodiments of the present disclosure, and illustrates a partial cross-section (I-I′) of a peripheral area PA of the display apparatus of FIG. 1 and a partial cross-section (II-II′) of a display area DA of the display apparatus of FIG. 2.

The first to third LED cells LC1, LC2 and LC3 provided as light sources of the sub-pixels SP1, SP2 and SP3 may include a semiconductor stack body 110 configured to emit light having different wavelengths. Each of the semiconductor stack bodies 110 may include a first conductive semiconductor layer 112, active layers 114R, 114G and 114B, and a second conductive semiconductor layer 116, and at least the active layers 114R, 114G and 114B may be configured to emit light having different wavelengths (e.g., red, green, blue) as described above.

As illustrated in FIG. 3, the semiconductor stack body 110 has a first surface facing the circuit board 200 and a second surface disposed opposite thereto. In one or more example embodiments, the first to third LED cells LC1, LC2 and LC3 may further include a first conductive semiconductor base layer 112B disposed on the first conductive semiconductor layer 112 and provided as the second surface of the semiconductor stack body 110. The first conductive semiconductor base layer 112B may have a single-layer structure shared by the first to third LED cells LC1, LC2 and LC3.

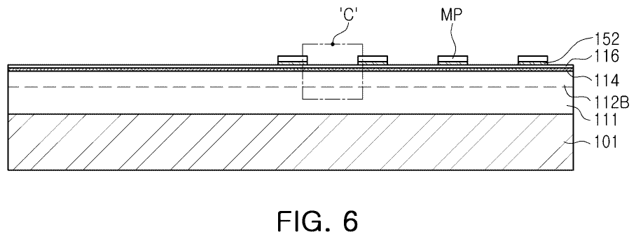

The semiconductor stack body 110 of the first to third LED cells LC1, LC2 and LC3 adopted in one or more example embodiments may include a nitride epitaxial layer grown on the same substrate. Referring to FIG. 6 together, a growth substrate 101 may include a substrate for nitride single crystal growth, for example, at least one of sapphire, Si, SiC, MgAl₂O₄, MgO, LiAlO₂, LiGaO₂, or GaN. In some example embodiments, in order to improve the crystallinity and light extraction efficiency of the nitride epitaxial layers, the growth substrate 101 may have a concave-convex structure on at least a portion of an upper surface thereof. In one or more examples, a surface having a concave-convex structure may have at least one concave structure formed thereon and at least one convex structure formed thereon.

Nitride epitaxial layers for the first to third LED cells LC1, LC2 and LC3 may be selectively grown in a desired area using different masks. Such nitride epitaxial layers may be formed using, for example, a metal organic chemical vapor deposition (MOCVD), a hydride vapor phase epitaxy (HVPE), or a molecular beam epitaxy (MBE) process.

As described above, the nitride epitaxial layer may include the first conductive semiconductor base layer 112B, the first conductive semiconductor layer 112, the active layers 114R, 114G and 114B, and the second conductive semiconductor layer 116.

In one or more example embodiments, the first to third active layers 114R, 114G and 114B of each of the first to third LED cells may include quantum well layers having different indium contents. In one or more examples, a quantum well layer may include a layer of material (e.g., semiconductor) between two layers of material with a wider bandgap to create a potential well that confines electrons and holes in one dimension, leading to quantized energy levels. In some example embodiments, each of the first to third active layers 114R, 114G and 114B may have a multi-quantum well structure in which quantum barrier layers and quantum well layers are alternately arranged. For example, the quantum well layer may be an InₓGa₁₋ₓN (0<x≤1) layer, and the quantum barrier layer may be a GaN layer or an AlGaN layer.

Each of the first conductive semiconductor base layer 112B and the first conductive semiconductor layer 112 may be nitride epitaxial layers having a composition of N-type InₓAl_{y}Ga_{1-x-y}N (where 0≤x<1, 0≤y<1, 0≤x+y<1). For example, the first conductive semiconductor layer 112 may be an N-type gallium nitride (n-GaN) layer doped with silicon (Si), germanium (Ge), or carbon (C). The second conductive semiconductor layer 116 may be a nitride semiconductor layer having a composition of P-type InₓAl_{y}Ga_{1-x-y}N (where 0≤x<1, 0≤y<1, 0≤x+y<1). For example, the second conductive semiconductor layer 116 may be a P-type gallium nitride (p-GaN) layer doped with magnesium (Mg) or zinc (Zn). Each of the first conductive semiconductor layer 112 and the second conductive semiconductor layer 116 may be formed as a single layer, but may also include a plurality of layers having different characteristics such as doping concentration and composition. The plurality of LED cells LC1, LC2 and LC3 may include a contact electrode 152 disposed on the second conductive semiconductor layers 116. The contact electrode 152 may include a highly reflective ohmic contact material or a transparent electrode material.

Referring to FIG. 4A, each side surface of the plurality of LED cells LC1, LC2 and LC3 may have a cell wave pattern 110CP. The cell wave pattern 110CP may be a pattern in which a plurality of cell concave portions 110PA and a plurality of cell convex portions 110PB alternately repeat at a regular cycle. For example, the plurality of cell concave portions 110PA and the plurality of cell convex portions 110PB may be alternately disposed. In one or more examples, two or more cell concave portions may be located between a pair of cell convex portions. In one or more examples, two or more cell convex portions may be located between a pair of concave portions. The cell concave portion 110PA may be defined as a portion recessed inwardly of the LED cell LC, and the cell convex portion 110PB may be defined as a portion protruding outwardly of the LED cell LC. The cell concave portions 110PA and the cell convex portion 110PB may be alternately repeated in a regular pattern. A distance between adjacent cell concave portions 110PA and a distance between adjacent cell convex portions 110PB may be constant, and the cell wave pattern 110CP may include a plurality of cell concave portions 110PA and a plurality of cell convex portions 110PB that are alternately repeated in a regular pattern. In one or more example embodiments, a distance between the cell concave portions 110PA and a distance between adjacent cell convex portions 110PB may be formed partially differently, and the cell wave pattern 110CP may include an irregular pattern. In one or more example embodiments, a degree of depression of the cell concave portions 110PA and a degree of protrusion of the cell convex portion 110PB may be constant, and the cell wave pattern 110CP may have a regular pattern. In one or more example embodiments, a depth of depression of the cell concave portions 110PA and a height of protrusion of the cell convex portion 110PB may be varied, and the cell wave pattern 110CP may have a pattern including a portion having an irregular height. A height difference between the cell concave portions 110PA and the cell convex portion 110PB, and a length of alternating repetitions may be larger or smaller than illustrated depending on the process method, and the number of the cell concave portions 110PA and the cell convex portion 110PB may also be larger or smaller than illustrated. When the height difference and the distance between the cell concave portions 110PA and the cell convex portion 110PB are significantly small, one or more example embodiments such as FIG. 4H may be included, and a description thereof will be given below. The cell wave pattern 110CP may be formed on a side surface of the first conductive semiconductor layer 112, a side surface of the active layer 114, and the side surface of the second conductive semiconductor layer 116. A side surface of the contact electrode 152 may be flat as compared to the cell wave pattern 110CP, and the cell wave pattern 110CP may not be formed on the side surface of the contact electrode 152. The cell wave pattern 110CP may be formed during a process of forming a plurality of LED cells LC1, LC2 and LC3, and a description thereof will be given below in the description of a manufacturing method.

An etching protective layer 118 may cover side surfaces of each of the plurality of LED cells LC1, LC2 and LC3. The etching protective layer 118 may be disposed between the plurality of LED cells LC1, LC2 and LC3 and a passivation layer 120. The etching protective layer 118 may cover the side surface of the first conductive semiconductor layer 112, the side surface of the active layer 114, and the side surface of the second conductive semiconductor layer 116. In one or more example embodiments, the etching protective layer 118 may further cover the side surface of the contact electrode 152. In one or more example embodiments, at least a portion of the passivation layer 120 may be spaced apart from the first conductive semiconductor base layer 112B, the first conductive semiconductor layer 112, the active layer 114, and the second conductive semiconductor layer 116 by the etching protective layer 118.

The etching protective layer 118 may conformally cover the cell wave pattern 110CP and may include a protective wave pattern 118CP including a plurality of protective concave portions 118PA and a plurality of protective convex portions 118PB corresponding to a plurality of cell concave portions 110PA and a plurality of cell convex portions 110PB of the cell wave pattern 110CP. In one or more example embodiments, the etching protective layer 118 may include a material having a carbon (C)-fluorine (F) bond. For example, the etching protective layer 118 may include a polymer including a C_{X}F_{Y} compound. In one or more example embodiments, the etching protective layer 118 may be a layer including nitrogen (N) that is bonded to the first conductive semiconductor base layer 112B, the first conductive semiconductor layer 112, the active layer 114 and the second conductive semiconductor layer 116, and may not be distinguished from an interface with the first conductive semiconductor base layer 112B, the first conductive semiconductor layer 112, the active layer 114, and the second conductive semiconductor layer 116. For example, the etching protective layer 118 may mean nitrogen (N) bonds disposed on side surfaces of the plurality of LED cells LC1, LC2 and LC3 formed to supplement nitrogen (N) bonds that are broken in an etching process, on side surfaces of the plurality of LED cells LC1, LC2 and LC3 including gallium nitride, for example, GaN, InGaN, or any other suitable material known to one of ordinary skill in the art.

The passivation layer 120 may be formed to cover the side surfaces and upper surfaces of the first to third LED cells LC1, LC2 and LC3. In one or more example embodiments, the passivation layer 120 may be formed up to a portion of the first conductive semiconductor base layer 112B between the first to third LED cells LC1, LC2 and LC3. In one or more examples, the passivation layer 120 may extend to a portion of the first conductive semiconductor base layer 112B disposed in the peripheral area PA. In one or more examples, the passivation layer 120 may be disposed to cover a lower surface of the first conductive semiconductor layer 112 in the connection area CR and the pad areas PAD, that is, in the peripheral area PA. The passivation layer 120 may cover at least a portion of the etching protective layer 118. In one or more example embodiments, the passivation layer 120 may include an insulating material. In one or more example embodiments, the passivation layer 120 may include at least one of SiO₂, SiN, SiCN, SiOC, SiON, SiOCN, SiOCN, HfOₓ, AlOₓ, ZrOₓ, or AlN. In one or more example embodiments, the passivation layer 120 may include a multilayer structure of ZrO₂/Al₂O₃/ZrO₂ and an insulating multilayer structure including at least one of SiO₂, SiN, SiCN, SiOC, SiON, or SiOCN. The present disclosure may minimize damage to the side surfaces of the LED cells LC in the process of forming the LED cells LC by including the etching protective layer 118, and thus, according to the embodiment, the passivation layer 120 formed to cure the side surfaces of the LED cells LC may not be disposed (see FIG. 4D).

In one or more example embodiments, a first connection electrode 130 may have a contact area connected to the first conductive semiconductor base layer 112B. In one or more examples, the first connection electrode 130 may be in direct contact with the first conductive semiconductor base layer 112B in an area between adjacent LED cells LC1, LC2 and LC3. In one or more examples, the first connection electrode 130 may be disposed to be electrically insulated from the first to third LED cells LC1, LC2 and LC3 by the passivation layer 120.

The first connection electrode 130 may be provided as a reflective electrode configured to emit light from the upper surfaces of the first to third LED cells LC1, LC2 and LC3. The first connection electrode 130 may have a reflective region 130R extending to the side surfaces of the LED cells. In a planar view, the first connection electrode 130 may have an integrated structure in which areas between adjacent the first to third LED cells LC1, LC2 and LC3 are connected to each other. For example, the first connecting electrode 130 may have an inverted U-shaped cross-section between the adjacent LED cells LC1, LC2 and LC3, and may have a grid or mesh shape in which the first connecting electrodes 130 extend in an X-direction and a Y-direction and are connected to each other.

The first connecting electrode 130 may include a reflective electrode material, and may include, for example, at least one of silver (Ag), nickel (Ni), aluminum (Al), chromium (CR), rhodium (Rh), iridium (Ir), palladium (Pd), ruthenium (Ru), magnesium (Mg), zinc (Zn), platinum (Pt), gold (Au), copper (Cu), titanium (Ti), tantalum (Ta), or tungsten (W). In some example embodiments, the first connecting electrode 130 may include compounds thereof, such as TaN, TiN, or a transparent electrode material, such as ITO, IZO, GAZO. In some example embodiments, the first connecting electrode 130 may comprise a single layer or multilayer structure of a conductive material.

As illustrated in FIG. 3, the first connection electrode 130 may have an extension portion 130E extending from the display area DA to the peripheral area PA. In the connection area CR, a common electrode 145 may be disposed on the extension portion 130E of the first connection electrode 130. A pad electrode 147 may be disposed in the pad area PAD, and may be disposed on the gap-fill insulating layer 141 similar to the common electrode 145, and may be connected to a bonding pad 199.

The pixel array 100 may further include a gap-fill insulating layer 141 covering the side surfaces and lower surfaces of the plurality of LED cells LC1, LC2 and LC3, and second connection electrodes 155 connected to the contact electrodes 152 of the plurality of LED cells LC1, LC2 and LC3 by penetrating through the gap-fill insulating layer 141.

An upper bonding structure 190 may include an upper bonding insulating layer 191 disposed on a lower surface of the gap-fill insulating layer 141, and upper bonding electrodes 195 electrically connected to the first and second connection electrodes 130 and 155 on the upper bonding insulating layer 191. The upper bonding electrodes 195 may be electrically connected to the first and second connection electrodes 130 and 155. The upper bonding electrodes 195 may have a shape like a post. Upper surfaces of the upper bonding electrodes 195 may have a substantially flat coplanar surface with an upper surface of the upper bonding insulating layer 191. The coplanar surface may be provided as a bonding surface for bonding to the circuit board 200 as a lower surface of the pixel array 100. The upper bonding electrodes 195 may include a conductive material, and may include, for example, copper (Cu). For example, the upper bonding insulating layer 191 may include at least one of SiO, SiN, SiCN, SiOC, SiON, or SiOCN.

As described above, the common electrode 145 and the pad electrode 147 may be disposed in the connection area CR and the pad areas PAD, respectively. The common electrode 145 may be provided as a common electrode structure for driving the LED cells LC1, LC2 and LC3 together with the first connection electrode 130. The pad electrode 147 may be disposed to be in contact with the bonding pad 199 in the pad areas PAD. The common electrode 145 and the pad electrode 147 may include a conductive material, for example, at least one of silver (Ag), nickel (Ni), aluminum (Al), chromium (CR), rhodium (Rh), iridium (Ir), palladium (Pd), ruthenium (Ru), magnesium (Mg), zinc (Zn), platinum (Pt), or gold (Au). The bonding pad 199 may include, for example, at least one of gold (Au), silver (Ag), or nickel (Ni).

In one or more example embodiments, depending on a connection target, the upper bonding electrodes 195 may include a first upper bonding electrode 195A electrically connected to the first connection electrode 130, second upper bonding electrodes 195B electrically connected to the second connection electrodes 155, and a third upper bonding electrode 195C connected to the pad electrode 147.

As illustrated in FIG. 3, the first upper bonding electrode 195A may be landed on the common electrode 145 by penetrating through the upper bonding insulating layer 191 and the gap-fill insulating layer 141, and may be commonly connected to one side (In one or more examples, the first conductive base semiconductor layer 112B) of each of the LED cells LC1, LC2 and LC3 through the common electrode 145 and the first connection electrode 130. The second upper bonding electrodes 195B may be landed on the first connection electrodes 130 by penetrating through the upper bonding insulating layer 191, and may be individually connected to the other side (In one or more examples, the second conductive semiconductor layer 116) of each of the LED cells LC1, LC2 and LC3 through the second connection electrode 155 and the contact electrode 152. In one or more examples, the third upper bonding electrode 195C may be landed on the pad electrode 147 by penetrating through the upper bonding insulating layer 191 and the gap-fill insulating layer 141, and may be connected to the bonding pad 199 for connection to an external circuit through the pad electrode 147.

Referring to FIG. 3, the circuit board 200 adopted in one or more example embodiments includes a device board 201 on which elements 220 for a driving circuit are disposed, and a lower bonding structure 290 disposed on the device board 201. The circuit board 200 may include an interlayer connection structure 230 between the device board 201 and the lower bonding structure 290. The interlayer connection structure 230 may include a interconnection insulation layer 231 on the device board 201, and an interconnection circuit 235 electrically connected to the driving elements 220 within the interconnection insulation layer 231. The elements 220 for the driving circuit may include thin film transistor (TFT) cells.

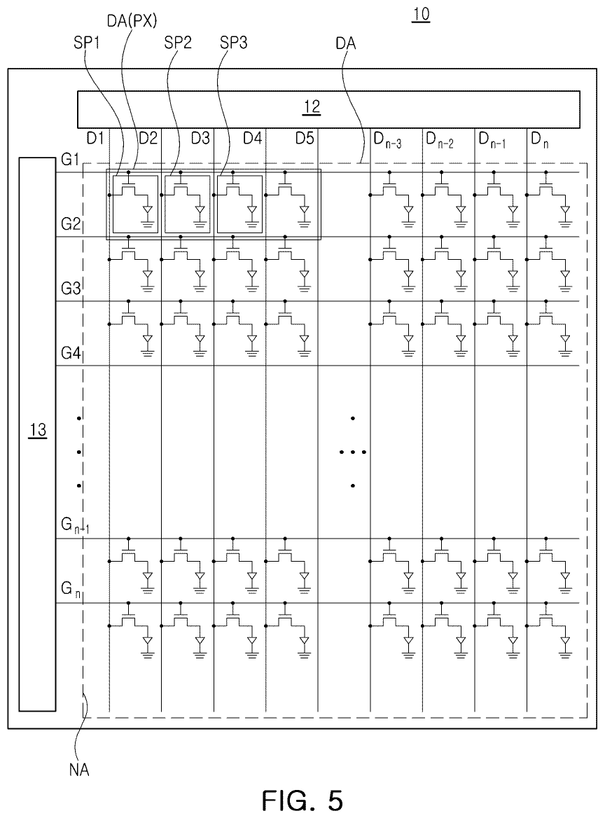

The device board 201 may be a semiconductor substrate including impurity regions including source/drain regions 205. The device board 201 may include, for example, a semiconductor such as silicon (Si) or germanium (Ge), or a compound semiconductor such as SiGe, SiC, GaAs, InAs, or InP. The driving circuit may include a circuit for controlling driving of pixels, particularly sub-pixels. The source region 205 of the TFT cells may be electrically connected to one side of the LED cells LC1, LC2 and LC3 through the interlayer connection structure 230 and the lower bonding structure 290. For example, the drain region 205 of the TFT cells may be connected to a data line through the interconnection circuit 235. Gate electrodes of the TFT cells may be connected to a gate line through the interconnection circuit 235. Such circuit components and operation will be described in more detail with reference to FIG. 5 below.

The lower bonding structure 290 may include a lower bonding insulating layer 291 and lower bonding electrodes 295 disposed on the lower bonding insulating layer 291 and electrically connected to the driving circuit. The lower bonding electrodes 295 may be electrically connected to the driving circuit through the interconnection circuit 235. For example, the lower bonding electrodes 295 may be provided in a pillar structure. Upper surfaces of the lower bonding electrodes 295 may have a substantially flat coplanar surface with an upper surface of the lower bonding insulating layer 291. The coplanar surface may be provided as a bonding surface for bonding to the pixel array 100 as the upper surface of the circuit board 200. The lower bonding electrodes 295 may include a conductive material, for example, copper (Cu). For example, the lower bonding insulating layer 291 may include at least one of SiO, SiN, SiCN, SiOC, SiON, or SiOCN.

The lower bonding electrodes 295 of the circuit board 200 and the upper bonding electrodes 195 of the pixel array 100 may be bonded to each other to provide an electrical connection path between the circuit board 200 and the pixel array 100. In one or more examples, the upper bonding insulating layer 191 of the pixel array 100 may be bonded to the lower bonding insulating layer 291 of the circuit board 200.

In this manner, the circuit board 200 and the pixel array 100 may be bonded to each other by bonding the lower bonding electrodes 295 and the upper bonding electrodes 195 and bonding the lower bonding insulating layer 291 and the upper bonding insulating layer 191. The bonding of the lower bonding electrodes 295 and the upper bonding electrodes 195 may be, for example, copper (Cu)-to-copper (Cu) bonding, and the bonding of the lower bonding insulating layer 291 and the upper bonding insulating layer 191 may be dielectric-to-dielectric bonding, for example, dielectric-to-dielectric bonding such as SiCN—SiCN bonding. The circuit board 200 and the pixel array 100 may be bonded to each other by hybrid bonding including copper (Cu)-to-copper (Cu) bonding and dielectric-to-dielectric bonding, and may be bonded without a separate adhesive layer.

Depending on the connection target, similarly to the upper bonding electrodes 195, the lower bonding electrodes 295 may be divided into first to third lower bonding electrodes 295A, 295B and 295C, respectively.

In one or more examples, a first lower bonding electrode 295A may be bonded to the first upper bonding electrode 195A, and may electrically connect each of first connection electrodes 130 to the driving circuit through the common electrode 145. Second lower bonding electrodes 295B may be bonded to the second upper bonding electrodes 195B, respectively, and may electrically connect the second connection electrode 155, which is an individual electrode, to the driving circuit.

In this manner, by bonding the first upper and lower bonding electrodes 195A and 295A and bonding the second upper and lower bonding electrodes 195B and 295B, the plurality of LED cells LC1, LC2 and LC3 may be connected to the driving circuit so as to be individually driven.

In one or more examples, a third lower bonding electrode 295C may be bonded to the third upper bonding electrode 195C to electrically connect the bonding pad 199 to the driving circuit through the pad electrode 145.

In one or more example embodiments, the lower bonding electrodes 295 may further include a lower dummy bonding electrode 295D not connected to the driving circuit. Similarly, the upper bonding electrodes 195 may further include an upper dummy bonding electrode 195D connected to the lower dummy bonding electrode 295D and not connected to the plurality of LED cells LC1, LC2 and LC3. The upper and lower dummy bonding electrodes 195D and 295D may be arranged at a uniform interval from the other lower bonding electrodes 195 and 295 over an entire area. In some example embodiments, the upper dummy bonding electrode 195D may be formed on a dummy pad 155D not connected to the plurality of LED cells LC1, LC2 and LC3, and the dummy pad 155D may be formed together with the second connection electrodes 155.

Microlenses 180 may be disposed on each of the LED cells LC1, LC2 and LC3 to focus light emitted from the LED cells LC1, LC2 and LC3. In one or more example embodiments, the microlenses 180 may be disposed on the first conductive base semiconductor layer 112B. The microlenses 180 may have a diameter greater than widths of the LED cells LC1, LC2 and LC3, for example, in the X-direction and the Y-direction. The microlenses 180 may be configured to control a beam angle of light emitted from the LED cells LC1, LC2 and LC3. The microlenses 180 may be formed of, for example, a transparent photoresist material or a transparent thermosetting resin film. The microlenses 180 adopted in this example embodiment are illustrated as having a form provided in the same shape and size, but in some example embodiments, the microlenses 180 may have different shapes and/or different sizes depending on an area of the first to third LED cells LC1, LC2 and LC3.

FIGS. 4B, 4C, 4D, 4E, 4F, 4G and 4H illustrate other example embodiments of FIG. 4A.

Referring to FIG. 4B together with FIG. 3, unlike the example embodiment of FIG. 4A, the etching protective layer 118 may not be formed on the side surface of the contact electrode 152. The etching protective layer 118 may cover the side surface of the first conductive semiconductor layer 112, the side surface of the active layer 114, and the side surface of the second conductive semiconductor layer 116, and may not cover the side surface of the contact electrode 152. The side surface of the first conductive semiconductor layer 112, the side surface of the active layer 114 and the side surface of the second conductive semiconductor layer 116 may be spaced apart from the passivation layer 120 by the etching protective layer 118, and the side surface of the contact electrode 152 may be in contact with the passivation layer 120. Whether the etching protective layer 118 covers the side of the contact electrode 152 may be modified by a process sequence and a process, a material included in the etching protective layer 118, or any other suitable material known to one of ordinary skill in the art. A description thereof will be given below in the description of the manufacturing method.

Referring to FIG. 4C together with FIG. 3, unlike the embodiment of FIG. 4A, the cell wave pattern 110CP may form portions of the side surfaces of the LED cell LC. The cell wave pattern 110CP may form at least a portion of the side surface of the second conductive semiconductor layer 116 and the side surface of the active layer 114, and may form a portion of the side surface of the first conductive semiconductor layer 112. An upper end of the cell wave pattern 110CP may be disposed adjacently to a lower portion of the side surface of the first conductive semiconductor layer 112. A cell flat pattern 110FP is a flat surface of the LED cell LC extending from the upper end of the cell wave pattern 110CP, and may form a portion of the side surface of the first conductive semiconductor layer 112. In one or more example embodiments, the cell flat pattern 110FP may include some concave-convex surfaces, but may have a surface roughness less than that of the cell wave pattern 110CP. The surface roughness indicates the degree of surface roughness, and may be expressed by parameters such as Arithmetic Average Roughness (Ra) or Average Maximum Height (Rz). The etching protective layer 118 may be disposed on the cell wave pattern 110CP of the LED cell LC and may cover portions of the side surfaces of the LED cell LC. In one or more example embodiments, the etching protective layer 118 may not cover the cell flat pattern 110FP. This example embodiment may be a structure formed by performing a plurality of different etching processes in a process of forming a plurality of LED cells LC1, LC2 and LC3. A description thereof will be given below in the description of the manufacturing method.

Referring to FIG. 4D together with FIG. 3, unlike the embodiment of FIG. 4A, the passivation layer 120 may be omitted. The passivation layer 120 may include a layer for curing defects on the side surface of the LED cell LC. The present disclosure may control defects on the side surface of the LED cell LC to not occur or to occur to a minimum by repeatedly performing an etching process of forming a plurality of LED cells LC1, LC2 and LC3 and a deposition process of a material constituting an etching protective layer 118, and thus, in one or more example embodiments, the passivation layer 120 may be omitted. In this example embodiment, the connection electrode 130 is omitted, but in one or more example embodiments, the first connection electrode 130 as in FIG. 4A may be included. In one or more example embodiments, unlike FIG. 4A, the first connection electrode 130 may not have a reflective region 130R extending to the side surface of the LED cells. Depending on the thickness of the etching protective layer 118, the material included in the etching protective layer 118, or any other suitable material known to one of ordinary skill in the art, the connection electrode 130 may be spaced apart from the first conductive semiconductor layer 112, the active layer 114 and the second conductive semiconductor layer 116.

Referring to FIG. 4E, unlike the embodiment of FIG. 4A, the etching protective layer 118 may be omitted. In one or more example embodiments, in order to increase the light efficiency of the etching protective layer 118 of the plurality of LED cells, if necessary, a process of removing the etching protective layer 118 may be additionally performed during the process, and a structure as in this example embodiment may be formed. In one or more examples, at least a portion of the side surface of the LED cell LC may include a cell wave pattern 110CP including a plurality of cell concave portions 110PA and a plurality of cell convex portions 110PB. The cell wave pattern 110CP of the LED cell LC may be in direct contact with the passivation layer 120.

Referring to FIG. 4F, unlike the example embodiment of FIG. 4A, the cell wave pattern 110CP including a plurality of cell concave portions 110PA and a plurality of cell convex portions 110PB may also be formed on a side surface of the contact electrode 152. The protective wave pattern 118CP of the etching protective layer 118 may also be formed on the side surface of the contact electrode 152. That is, portions of the plurality of protective concave portions 118PA and portions of the plurality of protective convex portions 118PB may be disposed on the side surface of the contact electrode 152. Depending on the manufacturing method, the side surface of the contact electrode 152 may also be affected by the process of forming the cell wave pattern 110CP, and a structure as in this example embodiment may be formed.

Referring to FIG. 4G, unlike the example embodiment of FIG. 4A, the etching protective layer 118 may cover not only the cell wave pattern 110CP, but also at least a portion of a lower surface of the first conductive semiconductor base layer 112B. The etching protective layer 118 may extend between the first conductive semiconductor base layer 112B and the passivation layer 120. In one or more example embodiments, a thickness of a portion in which the etching protective layer 118 covers the cell wave pattern 110CP may be greater than a thickness of a portion covering a lower surface of the first conductive semiconductor base layer 112B.

Referring to FIG. 4H, unlike the embodiment of FIG. 4A, the etching protective layer 118 covering the side surface of the LED cell LC may be included, but the side surface of the LED cell LC may not include the cell wave pattern 110CP, and the etching protective layer 118 may not have the protective wave pattern 118CP. Depending on the process method, in one or more example embodiments, the side surface of the LED cell LC may be formed such that a gap and a height difference between the cell concave portion 110PA and the cell convex portion 110PB of FIG. 4A is as small as several nm or less or several Armstrong units, and In one or more examples, a side surface on which a surface roughness having some concave-convex portions is formed may be formed without observing the cell wave pattern 110CP. The etching protective layer 118 covering the cell wave pattern 110CP may also have a form in which the surface roughness having some concave-convex portions is formed without observing the protective wave pattern 118CP.

FIG. 5 is a driving circuit diagram implemented in a display apparatus according to example embodiments.

Referring to FIG. 5, a circuit diagram of a display apparatus 10 in which n×n sub-pixels are arranged is illustrated. Each of the first to third sub-pixels SP1, SP2 and SP3 may accommodate data signals through data lines (D1-Dn) which are paths in a vertical direction, for example, a row direction. The first to third sub-pixels SP1, SP2 and SP3 may accommodate control signals, i.e., gate signals, through gate lines (G1-Gn) which are paths in a horizontal direction, for example, a column direction.

A plurality of pixels PX including the first to third sub-pixels SP1, SP2 and SP3 provide a display area DA, and the display area DA is an active area and is provided as a display area for a user. A non-active area NA (or a peripheral area PA) may be formed along one or more edges of the display area DA. The non-active area NA may extend along an outer periphery of a panel of the display apparatus 10.

First and second driver circuits 12 and 13 may be adopted to control an operation of the pixels PX, i.e., the first to third sub-pixels SP1, SP2 and SP3. Some or all of the first and second driver circuits 12 and 13 may be implemented on the circuit board 200. The first and second driver circuits 12 and 13 may be comprised of an integrated circuit, a thin film transistor panel circuit, or other suitable circuits, and may be disposed in the non-active area NA of the display apparatus 10. The first and second driver circuits 12 and 13 may include a microprocessor, a memory such as storage, a processing circuit, and a communication circuit.

In order to display an image by pixels PX, the first driver circuit 12 may supply image data to data lines (D1-Dn), and may simultaneously transmit clock signals and other control signals to the second driver circuit 13, which is a gate driver circuit. The second driver circuit 13 may be implemented using an integrated circuit and/or a thin film transistor circuit. A gate signal for controlling the first to third sub-pixels SP1, SP2 and SP3 arranged in the column direction may be transmitted through the gate lines (G1-Gn) of the display apparatus 10.

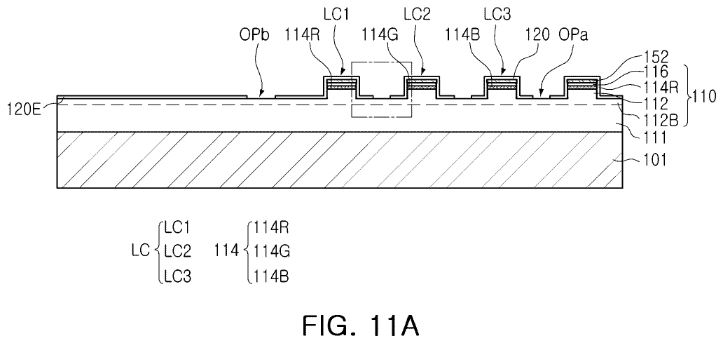

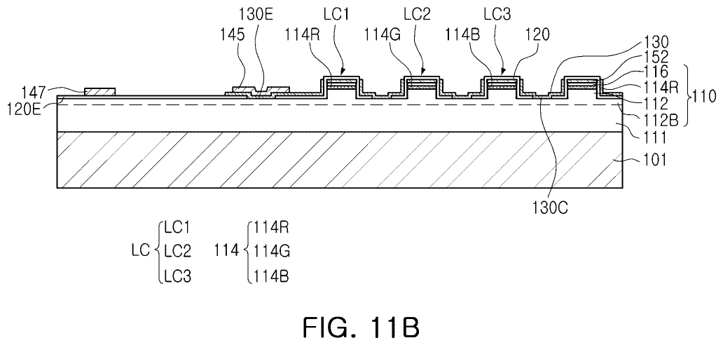

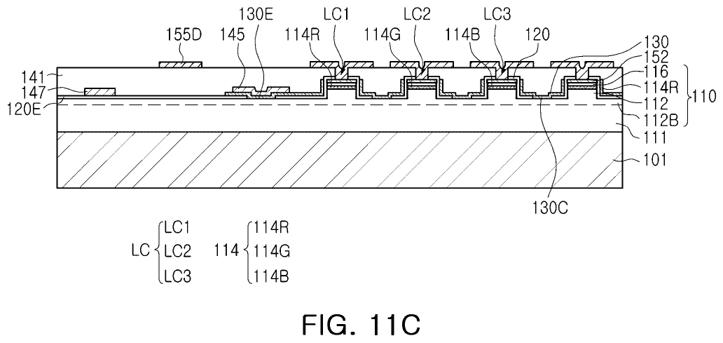

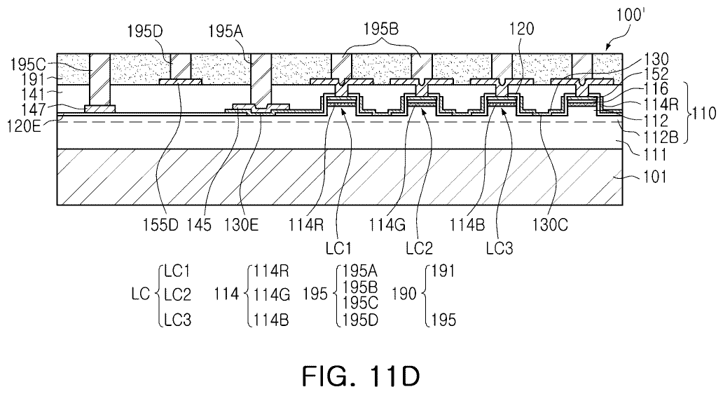

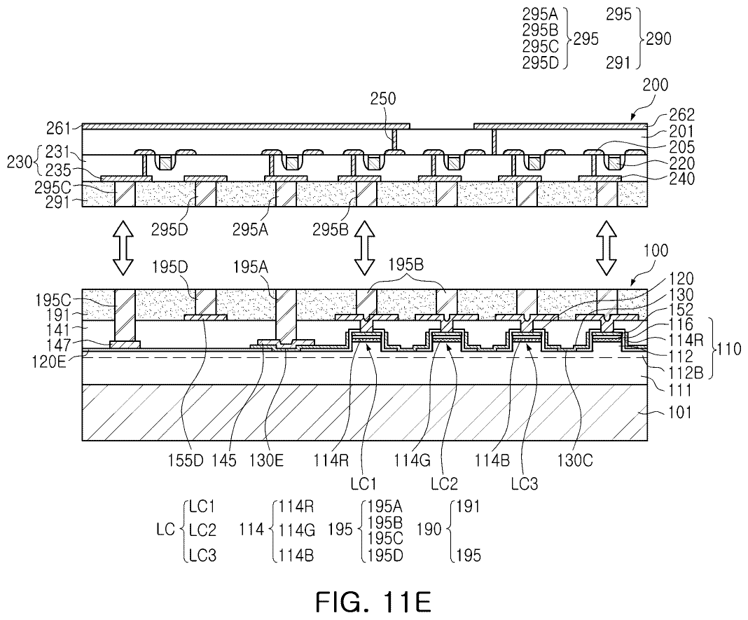

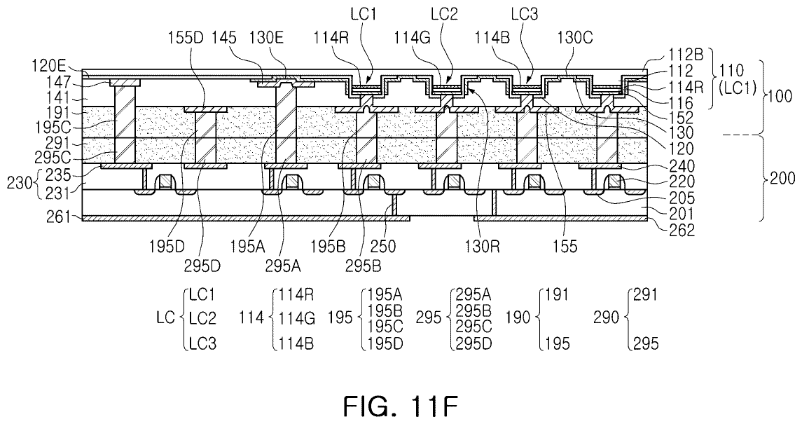

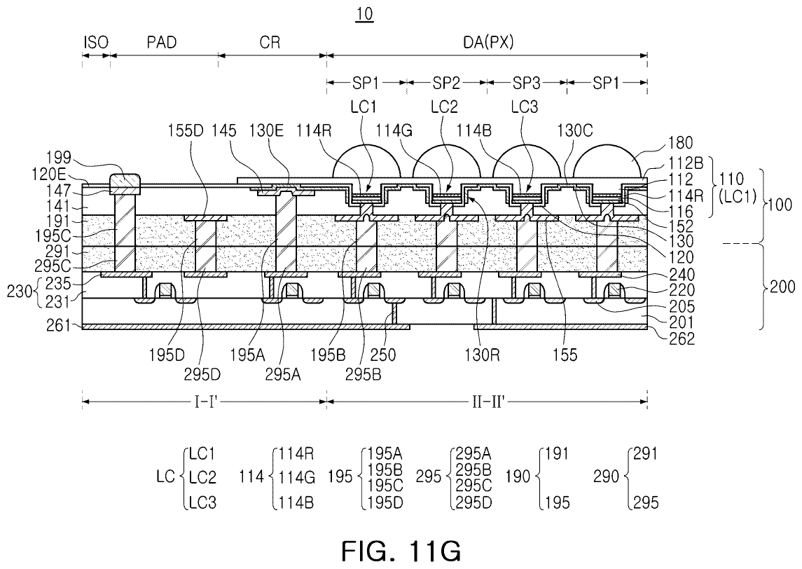

FIG. 6, FIG. 11A, FIG. 11B, FIG. 11C, FIG. 11D, FIG. 11E, FIG. 11F and FIG. 11G are cross-sectional views of major processes illustrating a manufacturing method of a display apparatus according to example embodiments.

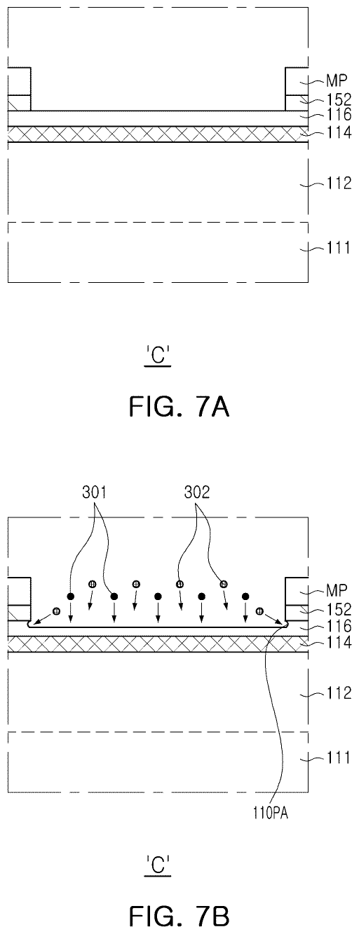

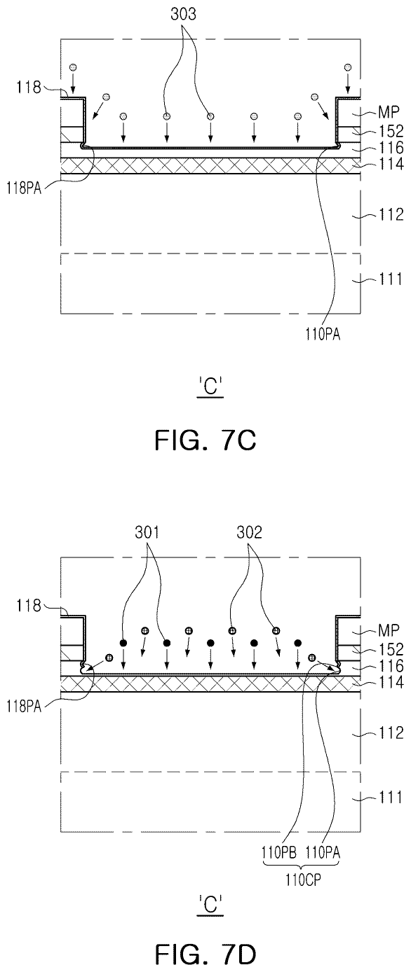

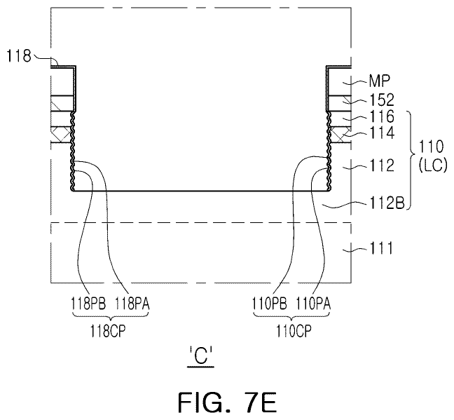

FIGS. 7A, 7B, 7C, 7D, and 7E are partial cross-sectional views of major processes illustrating a manufacturing method of a display apparatus according to example embodiments. FIGS. 7A, 7B, 7C, 7D, 7E and 7F are enlarged views of region ‘C’ of FIG. 6, and illustrates a manufacturing method corresponding to the example embodiment of FIG. 4A.

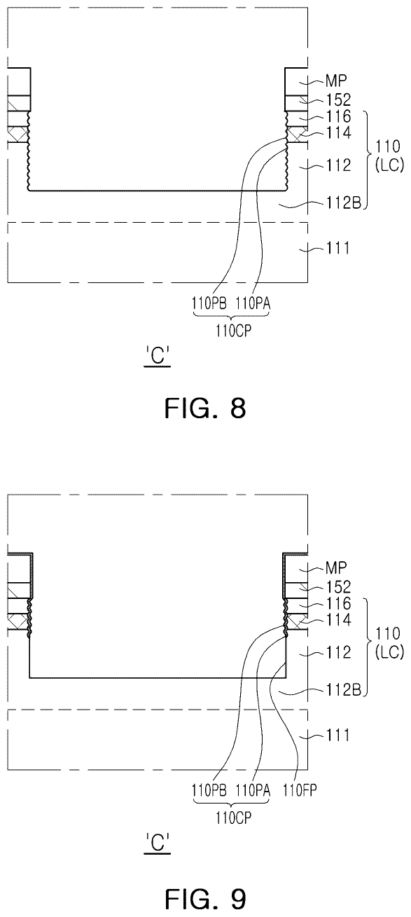

FIG. 8 is a partial cross-sectional view of major processes illustrating a manufacturing method of a display apparatus according to example embodiments. FIG. 8 is a partial cross-sectional view for explaining another example embodiment of a manufacturing method of a display apparatus.

FIG. 9 is a partial cross-sectional view of major processes illustrating a manufacturing method of a display apparatus according to example embodiments. FIG. 9 is a partial cross-sectional view for explaining another example embodiment of a manufacturing method of a display apparatus.

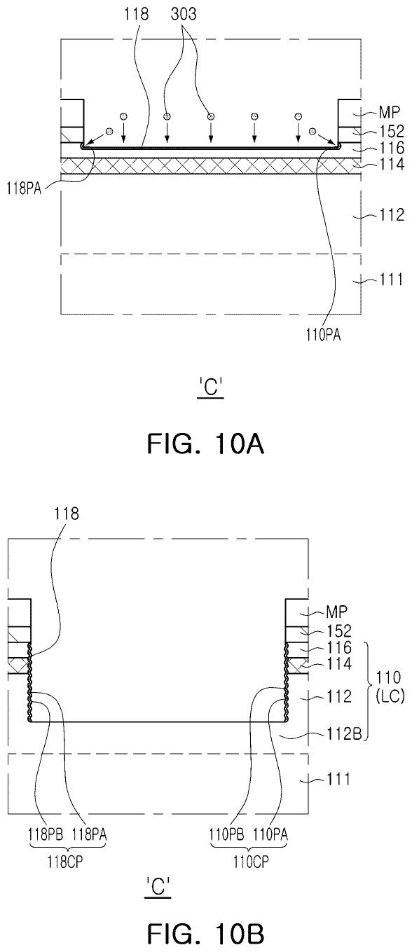

FIGS. 10A and 10B are partial cross-sectional views of major processes illustrating a manufacturing method of a display apparatus according to example embodiments. FIGS. 10A and 10B are partial cross-sectional views for explaining another example embodiment of a manufacturing method of a display apparatus.

Referring to FIGS. 6A and 7A, a semiconductor underlayer 111, a first conductive semiconductor base layer 112B, a first conductive semiconductor layer 112, an active layer 114 and a second conductive semiconductor layer 116 are sequentially formed on a growth substrate 101, and a contact electrode 152 and a mask pattern MP may be formed on the second conductive semiconductor layer 116. Referring also to FIG. 3, the contact electrode 152 and the mask pattern MP may be formed in an area in which a plurality of LED cells LC1, LC2 and LC3 are to be formed. In one or more example embodiments, the formation of the contact electrode 152 may be omitted in this operation, and a mask pattern MP may be formed directly on the second conductive semiconductor layer 116. In one or more examples, a separate process of forming the contact electrode 152 may be performed before the manufacturing operation of FIG. 11A. Referring to FIG. 7E together, the first conductive semiconductor base layer 112B, the first conductive semiconductor layer 112, the active layer 114, and the second conductive semiconductor layer 116 may form a semiconductor stack body 110.

The growth substrate 101 may be for growing nitride single crystal, and may include, for example, at least one of sapphire, Si, SiC, MgAl₂O₄, MgO, LiAlO₂, LiGaO₂, and GaN. In some example embodiments, in order to improve the crystallinity and light extraction efficiency of the semiconductor layers, the growth substrate 101 may have a concave-convex structure on at least a portion of an upper surface. In one or more examples, layers grown in an upper portion may also have concave-convex portions formed thereon.

The semiconductor underlayer 111, the first conductive base semiconductor layer 112B, the first to third active layers 114R, 114G and 114B, and the second conductive semiconductor layer 116 may be formed using, for example, a metal-organic chemical vapor deposition (MOCVD), hydrogenated vapor phase epitaxy (HVPE), or molecular beam epitaxy (MBE) process. In some example embodiments, the semiconductor underlayer 111 may include a buffer layer and an undoped nitride layer (e.g., GaN). In one or more examples, the buffer layer is for alleviating lattice defects of the first conductive semiconductor layer 112, and may include an undoped nitride semiconductor such as undoped GaN, undoped AlN, and undoped InGaN. The first conductive semiconductor layer 112 may form a portion of the upper portion of the first conductive base semiconductor layer 112B and may form an individual LED cell LC according to a subsequent process. The first conductive semiconductor base layer 112B and the first conductive semiconductor layer 112 may be N-type nitride semiconductor layers such as N-type GaN, and the second conductive semiconductor layer 116 may be a P-type nitride semiconductor layer such as P-type GaN/P-type AlGaN. The first to third active layers 114R, 114G and 114B may have a single quantum well or multi-quantum well structure such as InGaN/GaN. The contact electrode 152 may include a transparent electrode or a highly reflective ohmic contact layer.

FIGS. 7B to 7F illustrate a manufacturing method according to one or more example embodiments of the present disclosure, including a first etching process (e.g., Bosch process) that may be performed after the process of FIG. 7A.

Referring to FIG. 7B, an etching process may be performed using a mask pattern MP as an etching mask. This operation may be defined as a first operation of a first etching process. The first operation etching process of the first etching process may use a gas capable of etching gallium nitride, such as GaN, InGaN, or any other suitable material known to one of ordinary skill in the art. In one or more example embodiments, the first operation etching process may include a plasma etching process using ions 301 and radicals 302. The etching using ions 301 may be performed in a state of applying a high bias to the growth substrate 101, and may thus have relatively anisotropic etching properties. Through this, the second conductive semiconductor layer 116 may be partially removed from an upper portion thereof. Etching using the radicals 302 may have relatively isotropic etching properties. The radicals 302 may partially remove the second conductive semiconductor layer 116 from the upper portion thereof, and may partially etch a portion overlapping the mask pattern MP to form a cell concave portion 110PA. The ions 301 may include, for example, ionized boron (B), argon (Ar), or nitrogen (N). The radicals 302 may include a halogen element, for example, at least one of fluorine (F), chlorine (Cl), bromine (Br), or iodine (I). In one or more example embodiments, the first operation etching process of the first etching process may use a gas capable of etching GaN. For example, a gas including at least one of BCl₃, Cl₂, Br₂, HBr, BF₃, F₂, Ar, or N₂ may be used. In one or more example embodiments, the etching process of this operation may be performed using only radicals. In one or more example embodiments, the etching process of this operation may be performed using only ions 301. In one or more example embodiments, the etching process of this operation may alternately perform an etching process using the ions 301 and an etching process using the radicals 302.

Referring to FIG. 7C, an operation of forming an etching protective layer 118 may be performed after the first etching process. This operation may be defined as a second operation of the first etching process. The etching protective layer 118 may be formed by depositing a protective material 303. In this operation, by decomposing C_{X}F_{Y} gas in a plasma, an etching protective layer 118 including a C_{X}F_{Y}-based polymer may be formed on a side surface and a bottom surface of an etched region. A gas including C₄F₈ may be used, but the present disclosure is not limited thereto. For example, a gas including at least one of CF₄, C₂F₆, C₃F₈, C₄F₁₀, C₄F₆, and C₂F₄ may be used. In one or more example embodiments, this operation of forming the etching protective layer 118 may be performed by a method of depositing a polymer. The etching protective layer 118 may be formed not only on an exposed surface of the second conductive semiconductor layer 116, but also on the contact electrode 152 and the mask pattern MP. The time for depositing the protective material to form the etching protective layer 118, a thickness at which the etching protective layer 118 is formed, or any other operation, may be modified depending on the size and the gap of each LED cell, the degree of occurrence of side defects thereof, or any other properties.

Referring to FIG. 7D, the etching protective layer 118 may be partially etched to expose the second conductive semiconductor layer 116, and the second conductive semiconductor layer 116 may be etched to form an additional cell concave portion 110PA. An operation of partially etching the etching protective layer 118 to expose the semiconductor stack body may be defined as a third operation of the first etching process, and an operation of etching the exposed semiconductor stack body to form an additional cell concave portion 110PA may be defined as a fourth operation of the first etching process. The third and fourth operations may be performed sequentially, but may be performed simultaneously according to one or more example embodiments. Similarly to the process operation referring to FIG. 7B, this etching process may include a plasma etching process using the ions 301 and the radicals 302. After performing the third operation of removing the etching protective layer 118 disposed on a bottom surface by anisotropic etching using the ions 301 by applying a high bias to the growth substrate 101, the fourth operation of additionally forming the cell concave portion 110PA by isotropic etching using the radicals may be performed. Since the third operation has high anisotropic etching properties, the etching protective layer 118 on the cell concave portion 110PA may not be etched and the cell concave portion 110PA may be protected. That is, the cell concave portion 110PA may not be exposed in the third operation. In this operation, a protruding cell convex portion 110PB may be formed between the cell concave portions 110PA. In one or more examples, the first, second, and third operations may be performed sequentially. In one or more examples, one or more parts of the first, second, and third operations may be performed in parallel. For example, before the first operation is completed, a part of the second operation and/or third operation may be initiated.

Referring to FIG. 7E, by repeating the cycles of FIGS. 7B to 7D, i.e., the first etching process, a cell wave pattern 110CP may be formed by a target depth, and an etching protective layer 118 having a protective wave pattern 118CP having a plurality of protective concave portions 118PA and a plurality of protective convex portions 118PB may be formed. The etching protective layer 118 may cover the cell wave pattern 110CP and may not cover an exposed upper surface of the first conductive semiconductor base layer 112B. In one or more example embodiments, the etching protective layer 118 may not be removed and may remain on the exposed upper surface of the first conductive semiconductor base layer 112B, and In one or more examples, a display apparatus including an LED light source module having the example embodiment of FIG. 4G may be manufactured according to a subsequent process. Then, by performing the processes of FIGS. 11A to 11G, a display apparatus including the LED light source module of FIGS. 3 and 4A may be manufactured. In one or more example embodiments, the first etching process may be repeatedly performed until the growth substrate 101 is exposed.

The first etching process performed in FIGS. 7B to 7E may be performed in a low temperature environment ranging from −100° C. to 0° C. In one or more example embodiments, the first etching process may be performed in an ultra-low temperature environment of −150° C. to −30° C. or less. When the first etching process is performed in the ultra-low temperature environment, according to one or more example embodiments, the operation of forming an etching protective layer 118 by depositing the protective material as in FIG. 7C may be omitted.

By controlling the time, temperature, gas used, or any other process component, of each operation of performing the cycles of FIG. 7B to FIG. 7D, heights of the plurality of cell concave portions 110PA and the cell convex portions 110PB and gaps therebetween may be variously modified. For example, by shortening the progress time of each operation or lowering the process temperature, the heights of the plurality of cell concave portions 110PA and the cell convex portions 110PB and the gap therebetween may be formed in several nm or less or several Armstrong units, and In one or more examples, the example embodiment of FIG. 4H may be formed according to the subsequent process.

Referring to FIG. 8, after the operation in FIG. 7E, a process of removing the etching protective layer 118 may be further performed. The process of removing the etching protective layer 118 may be further performed when the process is determined to be necessary for increasing the light efficiency. In one or more example embodiments, the process of removing the etching protective layer 118 may be performed by a dry etching process using O₂ plasma, or a wet etching process using a solution for selectively etching the etching protective layer 118. Then, by performing the processes of FIGS. 11A to 11G, a display apparatus including the LED light source module of FIGS. 3 and 4E may be manufactured.

Referring to FIG. 9, after the operation in FIG. 7D, the cell wave pattern 110CP and the etching protective layer 118 are formed only to a portion lower than a lower surface of the active layer 114, that is, to a portion of an upper portion of the first conductive semiconductor layer 112, and then, a second etching process, which is an anisotropic etching process, may be performed so that the first conductive semiconductor layer 112 may be further etched by a desired depth by anisotropic etching. Through this, the semiconductor stack body 110 may be formed without causing side defects in the second conductive semiconductor layer 116 and the active layer 114, which may be particularly vulnerable to side defects. Accordingly, a display apparatus including the LED light source module of FIG. 3 and FIG. 4C may be manufactured. By quickly etching a portion of the first conductive semiconductor layer 112 by the anisotropic etching process, the process cost and process time may be reduced. In one or more example embodiments, the second etching process may be performed by a Reactive Ion Etching (RIE) process.

Referring to FIGS. 10A and 10B, the etching protective layer 118 may not be formed on the mask pattern MP and the contact electrode 152. Unlike depositing a C_{X}F_{Y}-based polymer on a side surface and a bottom surface of an etched area using C_{X}F_{Y} gas (e.g., C₄F₈) in the operation referring to FIG. 7C, in this example embodiment, a gas including N such as nitrogen (N₂) may be used. For example, by reacting nitrogen radicals on the side surface and the bottom surface of the etched area using at least one of N₂, NH₃, NO, N₂H₄, or N₂ plasma, it may be possible to complement defects in an etched surface of the second conductive semiconductor layer 116, the active layer 114 and the first conductive semiconductor layer 112. For example, the second conductive semiconductor layer 116, the active layer 114 and the first conductive semiconductor layer 112 may be nitride epitaxial layers, and may cause nitrogen bonds on the etching surface to be broken in the etching process referring to FIG. 7B. In this example embodiment, by restoring the broken nitrogen bonds using nitrogen radicals, the side defects of the second conductive semiconductor layer 116, the active layer 114, and the first conductive semiconductor layer 112 may be complemented. Since the reaction does not occur on the contact electrode 152 and the mask pattern MP, the display apparatus including the LED light source module of FIG. 3 and FIG. 4B may be manufactured by performing the subsequent process. The etching protective layer 118 may cover the cell wave pattern 110CP, and may not cover an exposed upper surface of the first conductive semiconductor base layer 112B. In one or more example embodiments, the etching protective layer 118 may not be removed and may remain on the exposed upper surface of the first conductive semiconductor base layer 112B. In one or more example embodiments, the etching protective layer 118 may be defined by nitrogen (N) bonded to each side surface of the second conductive semiconductor layer 116, the active layer 114 and the first conductive semiconductor layer 112, and may be integral with each side surface of the second conductive semiconductor layer 116, the active layer 114 and the first conductive semiconductor layer 112 so as not to have an interface distinct therefrom. In FIGS. 10A and 10B, the etching protective layer 118 is illustrated as an additional layer on the second conductive semiconductor layer 116, the active layer 114 and the first conductive semiconductor layer 112, but the etching protective layer 118 may be a changed portion of surfaces of the second conductive semiconductor layer 116, the active layer 114, and the first conductive semiconductor layer 112. For example, the etching protective layer 118 may refer to nitrogen (N) bonds disposed on the side surfaces of the plurality of LED cells LC1, LC2 and LC3 formed to supplement nitrogen (N) bonds broken in the etching process, on the side surfaces of the plurality of LED cells LC1, LC2 and LC3 including gallium nitride, for example, GaN, InGaN, or any other suitable material known to one of ordinary skill in the art.

Referring to FIG. 11A, a passivation layer 120 may be formed on the first to third LED cells LC1, LC2 and LC3, and first openings OPa opening a contact region of the first conductive base semiconductor layer 112B and a second opening OPb for a common electrode in the connection area may be formed.

The passivation layer 120 may be conformally formed on an upper surface of an epitaxial layer including the first to third LED cells LC1, LC2 and LC3. The passivation layer 120 may be formed by an atomic layer deposition (ALD) process. The passivation layer 120 may include, for example, at least one of SiO₂, SiN, SiCN, SiOC, SiON, SiOCN, SiOCN, HfOₓ, AlOₓ, ZrOₓ, or AlN. The passivation layer 120 may include a plurality of insulating layers. The passivation layer 120 may be provided as a layer for curing surface defects of the plurality of LED cells LC1, LC2 and LC3. The passivation layer 120 may include, for example, at least one of ZrO₂, Al₂O₃, or HfO₂. In some example embodiments, the passivation layer 120 may include a multilayer structure of ZrO₂/Al₂O₃/ZrO₂. In one or more example embodiments, the passivation layer 120 may include a second insulating layer 125 including at least one of SiO₂, SiN, SiCN, SiOC, SiON, or SiOCN. The passivation layer 120 may be formed not only on the display area DA, but may also have a portion 120E extending to the peripheral area PA.

Referring to FIG. 11B, a first connection electrode 130, a common electrode 145, and a pad electrode 147 may be formed.

First, a first connection electrode 130 may be formed to be connected to a first conductive base semiconductor layer 112B through the first openings OPa on an area of the passivation layer 120 between the plurality of LED cells LC1, LC2 and LC3. The first connection electrode 130 may extend onto the side surfaces of the LED cells LC1, LC2 and LC3 and may be provided as a reflective layer.

Next, the common electrode 145 and the pad electrode 147 may be formed on an extending portion 120E of the passivation layer (see FIG. 3) extending onto the connection area CR and the pad areas PAD, respectively. The common electrode 145 may be connected to the first conductive base semiconductor layer 112B through the second opening OPb. The common electrode 145 may be formed on the extension portion 130E of the first connection electrode 130, and the pad electrode 147 may be formed on the passivation layer 120. The common electrode 145 and the pad electrode 147 may be formed together through the same process.

Referring to FIG. 11C, a gap-fill insulating layer 141 may be formed, and second connection electrodes 155 connected to the contact electrodes 152 may be formed.

As the gap-fill insulating layer 141 may be formed to cover all of the structures formed in the preceding operations including the first connecting electrode 130, and then a process of flattening the gap-fill insulating layer 141 may be performed using a planarization process such as a chemical mechanical polishing (CMP) process or an etch-back process. For example, the gap-fill insulating layer 141 may be a low-κ dielectric such as silicon oxide.

Contact holes respectively opening the contact electrodes 155 by penetrating through the gap-fill insulating layer 141 and the passivation layer 120 are formed, and a conductive material is filled in the contact holes to form the contact electrodes 155. Some of the contact electrodes 155 may extend onto the gap-fill insulating layer 141.

Referring to FIG. 11D, an upper bonding insulating layer 191 may be formed on second electrodes 150, and upper bonding electrodes 195 may be formed.

The upper bonding insulating layer 191 may include a material identical to or different from the gap-fill insulating layer 141. The upper bonding electrodes 195 may form via holes penetrating through the upper bonding insulating layer 191 and the gap-fill insulating layer 141, and may fill the via holes with a conductive material, and may then planarize the upper bonding insulating layer and the upper bonding electrodes using a planarization process such as a CMP process. As a result, the upper bonding electrodes may have an upper surface that is substantially flat and coplanar with an upper surface of the upper bonding insulating layer.

Depending on the connection target, the upper bonding electrodes 195 may include a first upper bonding electrode 195A electrically connected to the first connection electrode 130, second upper bonding electrodes 195B electrically connected to the second connection electrodes 155, and a third upper bonding electrode 195C connected to the pad electrode 147. In one or more examples, the upper bonding electrodes 195 may further include a dummy bonding electrode 295D. Since the upper dummy bonding electrodes 195D are arranged at a uniform interval from the other lower bonding electrodes 195 and 295 over an entire area, a uniform planarization process may be performed over the entire area.

Referring to FIG. 11E, a pixel array structure including first to third LED cells LC1, LC2 and LC3 may be bonded to a circuit board 200.

The circuit board 200 may be prepared through a separate process. A pixel array 100′ and the circuit board 200 may be bonded on a wafer level by a wafer bonding method, for example, the hybrid bonding described above. The circuit board 200 may include a lower bonding structure 290 having a lower bonding insulating layer 291 and lower bonding electrodes 295, as described above. The lower bonding electrodes 295 may be bonded to the upper bonding electrodes 195, and the lower bonding insulating layer 291 may be bonded to the upper bonding insulating layer 191. In this manner, the pixel array 100′ including the LED cells LC1, LC2 and LC3 and the circuit board 200 may be bonded without a separate adhesive layer.

Referring to FIG. 11F, the growth substrate 101 may be removed, and a portion of the semiconductor stack body 110, i.e., the semiconductor underlayer 111, may be removed.

The growth substrate 101 may be removed by various processes such as laser lift-off, mechanical polishing or mechanical chemical polishing, and an etching process. The semiconductor underlayer 111 may be partially removed so that a thickness thereof may be reduced by a predetermined thickness, for example, using a polishing process such as CMP. After the semiconductor underlayer 111 is removed, the first conductive base semiconductor layer 112B may be exposed.

Referring to FIG. 11G, the first conductive base semiconductor layer 112B disposed in the pad area PAD may be further removed, and microlenses 180 and the bonding pads 199 (see FIG. 3) may be further formed, thereby manufacturing the display apparatus 10 illustrated in FIG. 3. In some example embodiments, the microlenses 180 may be formed to have different sizes according to the areas of the LED cells LC1, LC2 and LC3.

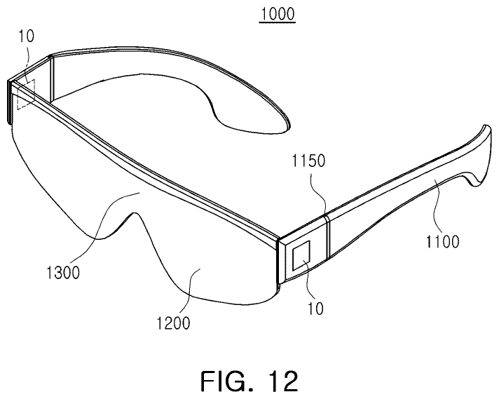

FIG. 12 is a schematic diagram of an electronic device including a display apparatus according to example embodiments.

Referring to FIG. 12, an electronic device 1000 according to one or more example embodiments may be a glasses-type display, which is a wearable device. The electronic device 1000 may include a pair of temples 1100, a pair of optical coupling lenses 1200, and a bridge 1300. The electronic device 1000 may further include a display apparatus 10 including an image generator.

The electronic device 1000 may be a head-mounted, glasses-type, or goggle-type virtual reality (VR) device, an augmented reality (AR) device, or a mixed reality (MR) device, which may provide virtual reality or provide virtual images and external real landscapes together.

The temples 1100 may extend in one direction. The temples 1100 may be spaced apart from each other and may extend in parallel. The temples 1100 may be folded toward the bridge 1300 using a hinge connection portion 1150. The bridge 1300 may be provided between the optical coupling lenses 1200, and may connect the optical coupling lenses 1200 to each other. The optical coupling lenses 1200 may include a light guide plate. The display apparatus 10 may be respectively disposed in a portion of the temples 1100 adjacent to the optical coupling lenses 1200 and may generate an image in the optical coupling lenses 1200. In some example embodiments, the display apparatus 10 may be disposed in a partial area of the optical coupling lenses 1200.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A manufacturing method of a light emitting diode (LED) module, the method comprising:
forming a semiconductor stack body by sequentially growing a first conductive semiconductor layer, an active layer, and a second conductive semiconductor layer on a growth substrate;
forming a mask pattern on the semiconductor stack body;
forming an LED cell by etching one or more portions of the second conductive semiconductor layer, the active layer, and the first conductive semiconductor layer; and
forming a gap-fill insulating layer on the LED cell,
wherein the forming the LED cell further comprises:
a first operation of partially removing the semiconductor stack body,
a second operation of forming an etching protective layer by covering an etched surface of the semiconductor stack body or forming a bond on the etched surface of the semiconductor stack body, and
a third operation of exposing the semiconductor stack body by partially removing the etching protective layer,
wherein at least a portion of a surface of the LED cell comprises a cell wave pattern including a cell concave portion recessed inwardly of the LED cell and a cell convex portion protruding outwardly of the LED cell.

2. The manufacturing method of an LED module of claim 1, wherein the forming an LED further comprises a cycle in which at least one of the first to third operations is repeatedly performed, and
wherein the cell wave pattern has at least one cell concave portion and at least one cell convex portion.

3. The manufacturing method of an LED module of claim 2, wherein forming the LED further comprises a fourth operation performed after the cycle in which at least one of the first to third operations is repeatedly performed,
wherein the fourth operation is an operation of etching a portion of the semiconductor stack body by a dry etching method using ionized plasma.

4. The manufacturing method of an LED module of claim 3, wherein the second conductive semiconductor layer and the active layer are etched by the cycle in which at least one of the first to third operations is repeatedly performed, and
wherein at least a portion of the first conductive semiconductor layer is etched by the fourth operation.

5. The manufacturing method of an LED module of claim 1, wherein at least a part of the first operation is performed by an isotropic etching process using radicals.

6. The manufacturing method of an LED module of claim 1, wherein the semiconductor stack body comprises gallium nitride, and
wherein the first operation uses a gas configured to etch the gallium nitride.

7. The manufacturing method of an LED module of claim 1, wherein the second operation uses a gas comprising a carbon (C)-fluorine (F) bond, and
wherein the etching protective layer comprises a CF-based polymer.

8. The manufacturing method of an LED module of claim 1, wherein at least a part of the third operation is performed by an anisotropic etching process using ionized plasma.

9. The manufacturing method of an LED module of claim 1, wherein the forming the mask pattern further comprises forming a contact electrode on the semiconductor stack body, and
wherein the mask pattern is formed on the contact electrode.

10. The manufacturing method of an LED module of claim 1, wherein the second operation further comprises covering the mask pattern with the etching protective layer.

11. The manufacturing method of an LED module of claim 1, wherein the second operation uses a gas comprising nitrogen (N),
wherein the semiconductor stack body comprises gallium (Ga), and
wherein the etching protective layer comprises nitrogen (N) coupled to the semiconductor stack body.

12. A manufacturing method of a light emitting diode (LED) module, comprising:
forming a semiconductor stack body by sequentially growing a first conductive semiconductor layer, an active layer and a second conductive semiconductor layer on a growth substrate; and
forming an LED cell by etching one or more portions of the second conductive semiconductor layer, the active layer, and the first conductive semiconductor layer,
wherein the forming the LED cell comprises a cycle in which at least one of an operation of etching the semiconductor stack body and an operation of forming an etching protective layer on the semiconductor stack body is repeatedly performed, and
wherein the etching protective layer has a protective wave pattern comprising at least one protective concave portion recessed inwardly of the LED cell and at least one protective convex portion protruding outwardly from the LED cell in a portion covering a surface of the LED cell.

13. The manufacturing method of an LED module of claim 12, wherein the protective wave pattern comprises a plurality of protective concave portions including the at least one protective concave portion and a plurality of protective convex portions including the at least one protective convex portion,
wherein the plurality of protective concave portions and the plurality of protective convex portions of the protective wave pattern are alternately disposed.

14. The manufacturing method of an LED module of claim 13, wherein the etching protective layer covers an entire surface of the second conductive semiconductor layer of the LED cell, an entire surface of the active layer, and at least a portion of a surface of the first conductive semiconductor layer.

15. The manufacturing method of an LED module of claim 12, wherein the operation of etching the semiconductor stack body further comprises an isotropic etching process using radicals, and
wherein the operation of forming the etching protective layer further comprises a process of depositing a polymer on the semiconductor stack body.

16. The manufacturing method of an LED module of claim 12, wherein the etching protective layer comprises a CF-based polymer.

17. A manufacturing method of an LED module, comprising:
forming a semiconductor stack body comprising gallium nitride on a growth substrate;
forming a contact electrode on the semiconductor stack body;
forming a mask pattern on the contact electrode; and
forming an LED cell by repeatedly performing a first etching process,
wherein the first etching process comprises:
partially removing the semiconductor stack body;
forming an etching protective layer by depositing a protective material on an etched surface of the semiconductor stack body, and
exposing the semiconductor stack body by partially removing the etching protective layer,
wherein the partially removing the semiconductor stack body in the first etching process forms a recessed cell concave portion on a surface of the LED cell, and
wherein the recessed cell concave portion comprises a portion overlapping the contact electrode.

18. The manufacturing method of an LED module of claim 17, wherein in the exposing of the semiconductor stack body by partially removing the etching protective layer, at least a portion of the recessed cell concave portion is not exposed.

19. The manufacturing method of an LED module of claim 17, wherein at least a part of the operations included in the first etching process uses a gas comprising at least one of BCl₃, Cl₂, Ar or N₂.

20. The manufacturing method of an LED module of claim 17, wherein the forming the LED cell further comprises a second etching process performed after repeatedly performing the first etching process, and
wherein the second etching process further comprises an operation of etching a portion of the semiconductor stack body by a dry etching method using ionized plasma.
